(19) United States
(12) Patent Application Publication
(10) Pub. No.: US 2008/0130075 A1
(43) Pub. Date: Jun. 5, 2008

(54) Hologram element, method for manufacturing the same, and hologram laser and optical pickup employing the hologram element

(75) Inventor: Munesato Kumagai, Mihara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/987,770

(22) Filed: Dec. 4, 2007

(30) Foreign Application Priority Data
Dec. 4, 2006 (JP) 2006-327484

(51) Int. Cl. G02B 5/32; G03F 7/00; G03H 1/00

(52) U.S. Cl. 359/15; 430/2; 359/1

(57) ABSTRACT

A hologram element is composed of a hologram element body shaped as a right prism having two rhombus-shaped bottom surfaces. A hologram is disposed on one bottom surface of the hologram element body, the hologram being divided by a division line into a plurality of regions having different grating periods. A grating is disposed on another bottom surface of the hologram element body. A first diagonal line of the bottom surface is longer than a second diagonal line thereof. A center of the hologram is located at a point of intersection of the first diagonal line and the second diagonal line. The division line lies in the first diagonal line. Light which enters through the one bottom surface having the hologram illuminates a plane which is perpendicular to the one bottom surface and includes the division line.

### CROSS-REFERENCE TO RELATED APPLICATION

This application claims priority to Japanese Patent Application No. 2006-327484, which was filed on Dec. 4, 2006, the contents of which are incorporated herein by reference in its entirety.

### BACKGROUND OF THE INVENTION

1. Field of the Invention

The present invention relates to a hologram element which is used in the production of a semiconductor laser device adaptable for use in, for example, an optical pickup apparatus which allows reproduction, recording or erasing of information borne in an information recording medium such as an optical disk.

2. Description of the Related Art

In an optical pickup apparatus which allows reproduction, recording or erasing of information borne in an information recording medium such as a CD (Compact Disk), a MD (Mini Disc), or a DVD (Digital Versatile Disk), a semiconductor laser device is utilized. Moreover, in recent years, there has been developed a so-called hologram laser constructed by incorporating a semiconductor laser element, a hologram element, and a signal detection light-receiving element into a single package. In this construction, a light beam is emitted from the semiconductor laser element, and the light beam which returned after being reflected from an optical disk, namely an optical recording medium is diffracted by the hologram element. The diffracted light beam is directed to the signal detection light-receiving element disposed in a location away from an optical axis.

In the hologram laser, the hologram element used as an optical component serves as an indispensable constituent, while at present the cost of components constituting the hologram element forms a significant proportion of the cost of manufacturing the hologram laser as a whole. Therefore, the cutting of manufacturing cost through a downsizing of the hologram element is a matter of essential to a reduction in the cost for the hologram laser that results from market competition.

Heretofore it has been customary to use such a hologram element as constructed by performing a pattern molding process on a soda glass or quartz glass substrate in accordance with a photo etching processing technique. In recent years, however, for the purpose of cost reduction, there have been developed plastic-made hologram elements constructed by means of resin molding technique-based pattern molding, as disclosed in Japanese Unexamined Patent Publication JP-A 10-187014 (1998) and Japanese Unexamined Patent Publication JP-A 10-254335 (1998).

FIG. 13A is a perspective view showing a hologram element 111 of conventional design, and FIG. 13B is a top view thereof. The conventional hologram element 111 has a shape of a rectangular parallelepiped, and has rectangular bottom surfaces. A circular hologram 112 is disposed on a hologram surface. The hologram 112 is divided into two semicircular regions 112a and 112b by a division line 113. The regions 112a and 112b have different grating periods. Moreover, a grating 114 is disposed on a grating surface.

The center of the hologram is located at a point of intersection of a first diagonal line and a second diagonal line on the hologram surface. The division line 113 is parallel to a direction longitudinally of the rectangular parallelepiped.

The hologram element 111 having rectangular hologram surface and grating surface is manufactured by a method for shaping a wafer to be in the form of chips through a dicing operation. In order to obtain a hologram element constructed in chip form, the dicing operation needs to be carried out in at least two directions in an equidistant manner. In this case, after cutting in the first direction is completed, at the time of performing cutting in the second direction, a dicing edge advances in a direction perpendicular to a dicing line corresponding to the first direction. Thus, the dicing edge can be prevented from wobbling.

Light which enters through the hologram surface of the hologram element illuminates a certain region on a plane which is perpendicular to the bottom surface and includes the division line. Therefore, it is possible to attain an optical capability of satisfactory level so long as there is provided, in a direction in which the light entering from the hologram surface is diffracted, a region for allowing the passage of diffraction light originating in the light entering from the hologram surface through the grating surface. However, the negative side is that the hologram element having the rectangular hologram surface and grating surface is large-sized and is thus produced at high cost. In this regard, in the case of producing a hologram element whose hologram surface and grating surface are not shaped in rectangle but take on another shape, at the time of performing cutting on the wafer in the second direction following the completion of cutting in the first direction, the dicing edge advances in a direction which is not perpendicular to the dicing line corresponding to the first direction. As a result, due to the force with which the edge is moved forward, a wobbling takes place in a direction in which it is relieved. Furthermore, although the wafer is stuck to an adhesive sheet, after being subdivided by the dicing operation in the first direction, it is no longer kept in a completely fixed state and is thus somewhat distorted against external forces. This makes it impossible to achieve an intended configuration at the time of performing cutting in the second direction. Such an inconvenience comes to the fore particularly in a case where the sharpness of the dicing edge has been blunted as the result of repeated use. The inconvenience comes to the fore also in a case where the hologram element is made of glass, as has been conventional, because it is so hard that cutting becomes difficult. After all, to date it has proved difficult to manufacture such a hologram element as has a configuration other than a rectangular shape in terms of attainment of dimensional accuracy in the hologram element.

However, plastic-made hologram elements have come to be predominant at the present time. Accordingly, by virtue of current-day dicing technique innovation and advancement of plastic-made base materials, the manufacture of a hologram element having a configuration other than a rectangular shape can be achieved satisfactorily with stability.

### SUMMARY OF THE INVENTION

The invention has been devised in an effort to solve the problems with the conventional art, and accordingly its object is to provide a hologram element which can be made compact without impairing its optical capability and can be produced at lower cost.

The invention provides a hologram element comprising:

a hologram element body shaped as a right prism having rhombus-shaped bottom surfaces;

a hologram disposed on one of the bottom surfaces of the hologram element body, the hologram being divided by a division line into a plurality of regions having different grating periods; and

a grating disposed on another of the bottom surfaces of the hologram element body,

on the rhombus-shaped bottom surface, a first diagonal line of the respective rhombus-shaped bottom surfaces being longer than a second diagonal line thereof,

a center of the hologram being located at a point of intersection of the first diagonal line and the second diagonal line,

the division line lying in the first diagonal line, and

light which enters through the one bottom surface having the hologram illuminating a plane which is perpendicular to the one bottom surface and includes the division line.

According to the invention, the hologram element is shaped as a right prism, and its bottom surfaces have a shape of a rhombus. The hologram element has a hologram disposed on one of the bottom surfaces, and has a grating disposed on another of the bottom surfaces. The hologram is divided by a division line into two regions having different grating periods. On the bottom surface, the first diagonal line is longer than the second diagonal line. The center of the hologram is located at a point of intersection of the first diagonal line and the second diagonal line of the one bottom surface. The division line lies in the first diagonal line. The light which enters through the one bottom surface illuminates down onto a plane which is perpendicular to the bottom surface and includes the division line.

In order to secure a region for allowing the passage of the light entering from the one bottom surface through the other bottom surface, in a direction in which the light entering from the one bottom surface is diffracted, the hologram element is such configured that the one bottom surface and the other bottom surface have a shape of a rhombus and the division line lies in the first diagonal line of the rhombus which is a longer one of the diagonal lines. This makes it possible to secure a sufficient length in a direction in which the division line of the one bottom surface extends, as well as to secure a region for allowing the passage of the light entering from the one bottom surface through the other bottom surface, while reducing the areas of the one bottom surface and the other bottom surface. By doing so, the substantial cubic volume of the hologram element can be reduced thereby to achieve miniaturization without impairing the optical capability required of the hologram element. Moreover, the number of hologram elements to be obtained from a wafer is increased, which leads to a reduction in the cost of manufacturing the hologram element apiece. Further, it is possible to reduce light which travels as noise toward the signal detection light-receiving element because of diffused reflection of laser light that occurs on the one bottom surface and the other bottom surface in accompaniment with the decrease of the areas of the one bottom surface and the other bottom surface, which leads to improvement in S/N ratio.

Moreover, in a dicing operation to produce-hologram elements in chip form by cutting a wafer having a plurality of holograms and gratings, with the provision of dicing lines in two directions, it is possible to allow easy manufacture. In addition, the hologram elements can be produced efficiently without causing any needless region in the wafer to be discarded.

The invention provides a hologram element comprising:

a hologram element body shaped as a right prism having isosceles triangle-shaped bottom surfaces;

a hologram disposed on one of the bottom surfaces of the hologram element body, the hologram being divided by a division line into a plurality of regions having different grating periods; and

a grating disposed on another of the bottom surfaces of the hologram element body,

the division line lying in a bisector of a vertex angle of the isosceles triangle-shaped bottom surface, and

light which enters through the one bottom surface having the hologram illuminating, out of a plane which is perpendicular to the one bottom surface and includes the division line, a region located closer to the vertex angle of the isosceles triangle-shaped bottom surface relative to a center of the hologram.

According to the invention, the hologram element is shaped as a right prism, and its bottom surfaces have a shape of isosceles triangle. The hologram element has a hologram disposed on one of the bottom surfaces, and has a grating disposed on another of the bottom surfaces opposite the one bottom surface. The hologram is divided by a division line into two regions having different grating periods. The division line lies in the bisector of the vertex angle of the isosceles triangle. The light which enters through the one bottom surface illuminates down onto, out of a plane which is perpendicular to the bottom surface and includes the division line, a region located closer to the vertex angle of the isosceles triangle relative to the center of the hologram.

In order to secure a region for allowing the passage of the light entering from the one bottom surface through the other bottom surface, in a direction in which the light entering from the one bottom surface is diffracted, the hologram element is so configured that the one bottom surface and the other bottom surface have a shape of isosceles triangle, and the division line lies in the bisector of the vertex angle of the isosceles triangle. This makes it possible to secure a sufficient length in a direction in which the division line of the one bottom surface extends, as well as to secure a region for allowing the passage of the light entering from the one bottom surface through the other bottom surface, while reducing the areas of the one bottom surface and the other bottom surface. By doing so, the substantial cubic volume of the hologram element can be reduced thereby to achieve miniaturization without impairing the optical capability required of the hologram element. Moreover, the number of hologram elements to be obtained from a wafer is increased, which leads to a reduction in the cost of manufacturing the hologram element apiece. Further, it is possible to reduce light which travels as noise toward the signal detection light-receiving element because of diffused reflection of laser light that occurs on the one bottom surface and the other bottom surface in accompaniment with the decrease of the areas of the one bottom surface and the other bottom surface, which leads to improvement in S/N ratio.

Moreover, in a dicing operation to produce hologram elements in chip form by cutting a wafer having a plurality of holograms and gratings, with the provision of dicing lines in three directions, it is possible to allow easy manufacture. In addition, the hologram elements can be produced efficiently without causing any needless region in the wafer to be discarded.

The invention provides a hologram element comprising:

a hologram element body shaped as a right prism having regular triangle-shaped bottom surfaces;

a hologram disposed on one of the bottom surfaces of the hologram element body, the hologram being divided by a division line into a plurality of regions having different grating periods; and

a grating disposed on another of the bottom surfaces of the hologram element body,

the division line lying in a bisector of any of the angles of the regular triangle-shaped bottom surface,

light which enters through the one bottom surface having the hologram illuminating, out of a plane which is perpendicular to the one bottom surface and includes the division line, a region located closer to the angle of the regular triangle-shaped bottom surface relative to a center of the hologram.

According to the invention, the hologram element is shaped as a right prism, and its bottom surfaces have a shape of a regular triangle. The hologram element has a hologram disposed on one of the bottom surfaces, and has a grating disposed on another of the bottom surfaces opposite the one bottom surface. The hologram is divided by a division line into two regions having different grating periods. The division line lies in the bisector of any of the angles of the regular triangle. The light which enters through the one bottom surface illuminates down onto, out of a plane which is perpendicular to the bottom surface and includes the division line, a region located closer to the angle of the regular triangle relative to the center of the hologram.

In order to secure a region for allowing the passage of the light entering from the one bottom surface through the other bottom surfaces in a direction in which the light entering from the one bottom surface is diffracted, the hologram element is so configured that the one bottom surface and the other bottom surface have a shape of a regular triangle, and the division line lies in the bisector of any of the angles of the regular triangle. This makes it possible to secure a sufficient length in a direction in which the division line of the one bottom surface extends, as well as to secure a region for allowing the passage of the light entering from the one bottom surface through the other bottom surface, while reducing the areas of the one bottom surface and the other bottom surface. By doing so, the substantial cubic volume of the hologram element can be reduced thereby to achieve miniaturization without impairing the optical capability required of the hologram element. Moreover, the number of hologram elements to be obtained from a wafer is increased, which leads to a reduction in costs of manufacturing the hologram element apiece. Further, it is possible to reduce light which travels as noise toward the signal detection light-receiving element because of diffused reflection of laser light that occurs on the one bottom surface and the other bottom surface in accompaniment with the decrease of the areas of the one bottom surface and the other bottom surface, which leads to improvement in S/N ratio.

Moreover, in a dicing operation to produce hologram elements in chip form by cutting a wafer having a plurality of holograms and gratings, with the provision of dicing lines in three directions, it is possible to allow easy manufacture. In addition, the hologram elements can be produced efficiently without causing any needless region in the wafer to be discarded.

The invention provides a method for manufacturing a hologram element mentioned above, comprising:

a dicing step of cutting a wafer having a plurality of the holograms and the gratings into chips,

in the dicing step, the wafer being subjected to cutting in accordance with equi-spaced first cutting lines and equi-spaced second cutting lines,

the first cutting line and the second cutting line making an acute angle with each other,

a point of intersection of the first cutting line and the second cutting line lying in a line extending from the division line, as well as in a line extending from a perpendicular bisector of the division line, and

the division line lying in a bisector of the acute angle.

According to the invention, the method for manufacturing a hologram element having rhombus-shaped bottom surfaces comprises a dicing step of cutting a wafer having a plurality of holograms and gratings into chips. In the dicing step, the wafer is subjected to cutting in accordance with the equi-spaced first cutting lines and the equi-spaced second cutting lines. The first cutting line and the second cutting line make an acute angle with each other. The point of intersection of the first cutting line and the second cutting line lies in a line extending from the division line, as well as in a line extending from the perpendicular bisector of the division line. Moreover, the division line lies in a bisector of the acute angle which the first cutting line forms with the second cutting line.

In this way, it is possible to produce the hologram element, in which a sufficient length can be secured in a direction in which the division line of the one bottom surface extends and the areas of the one bottom surface and the other bottom surface can be reduced, with ease by using dicing lines in two directions. Moreover, the hologram elements can be produced efficiently without causing any needless region in the wafer to be discarded. Further, the number of hologram elements to be obtained from the wafer is increased, which leads to a reduction in the cost of manufacturing the hologram element apiece.

The invention provides a method for manufacturing a hologram element mentioned above, comprising:

a formation step of forming holograms and gratings on a wafer; and

a dicing step of cutting the wafer having a plurality of the holograms and the gratings into chips,

in the formation step, the holograms and the gratings being formed so as to be each 180° rotationally symmetrical with a hologram or grating adjacent thereto, about centers of the holograms and the gratings each regarded as a center of rotation,

and in the dicing step, the wafer being subjected to cutting in accordance with equi-spaced first cutting lines, equi-spaced second cutting lines, and equi-spaced third cutting lines; the first cutting line and the second cutting line making an acute angle of smaller than 60° with each other; the third cutting line lying in a perpendicular bisector of an obtuse angle which the first cutting line forms with the second cutting line; and the division line lying in a bisector of the acute angle.

According to the invention, the method for manufacturing the hologram element having isosceles triangle-shaped bottom surfaces comprises the formation step of forming holograms and gratings on a wafer and the dicing step of cutting the wafer having a plurality of the holograms and the gratings into chips. In the formation step, the holograms and the gratings are formed so as to be each 180° rotationally symmetrical with a hologram or grating adjacent thereto, about centers of the holograms and the gratings each regarded as the center of rotation. In the dicing step, the wafer is subjected to cutting in accordance with the equi-spaced first cutting lines, the equi-spaced second cutting lines, and the equi-spaced third cutting lines. The first cutting line and the second cutting line make an acute angle of smaller than 60° with each other. The third cutting line lies in the perpendicular bisector of the obtuse angle which the first cutting line forms with the second cutting line. Moreover, the division line lies in the bisector of the acute angle which the first cutting line forms with the second cutting line.

In this way, it is possible to produce the hologram element, in which a sufficient length can be secured in a direction in which the division line of the one bottom surface extends and the areas of the one bottom surface and the other bottom surface can be reduced, with ease by using dicing lines in three directions. Moreover, the hologram elements can be produced efficiently without causing any needless region in the wafer to be discarded. Further, the number of hologram elements to be obtained from the wafer is increased, which leads to a reduction in the cost of manufacturing the hologram element apiece.

The invention provides a method for manufacturing a hologram element mentioned above, comprising:

a formation step of forming holograms and gratings on a wafer; and

a dicing step of cutting the wafer having a plurality of the holograms and the gratings into chips,

in the formation step, the holograms and the gratings being formed so as to be each 180° rotationally symmetrical with a hologram or grating adjacent thereto, about centers of the holograms and the gratings each regarded as a center of rotation,

and in the dicing step, the wafer being subjected to cutting in accordance with equi-spaced first cutting lines, equi-spaced second cutting lines, and equi-spaced third cutting lines; the first cutting line, the second cutting line, and the third cutting line make an angle of 60° with one another; and the division line lies in a bisector of the angle which the first cutting line forms with the second cutting line.

According to the invention, a method for manufacturing a hologram element having regular triangle-shaped bottom surfaces comprises a formation step of forming holograms and gratings on a wafer and a dicing step of cutting the wafer having a plurality of the holograms and the gratings into chips. In the formation step, the holograms and the gratings are formed so as to be each 180° rotationally symmetrical with a hologram or grating adjacent thereto, about centers of the holograms and the gratings each regarded as the center of rotation. In the dicing step, the wafer is subjected to cutting in accordance with the equi-spaced first cutting lines, the equi-spaced second cutting lines, and the equi-spaced third cutting lines. The first cutting line, the second cutting line, and the third cutting line make an angle of 60° with one another. Moreover, the division line lies in the bisector of the angle which the first cutting line forms with the second cutting line.

In this way, it is possible to produce the hologram element, in which a sufficient length can be secured in a direction in which the division line of the one bottom surface extends and the areas of the one bottom surface and the other bottom surface can be reduced, with ease by using dicing lines in three directions. Moreover, the hologram elements can be produced efficiently without causing any needless region in the wafer to be discarded. Further, the number of hologram elements to be obtained from the wafer is increased, which leads to a reduction in the cost of manufacturing the hologram element apiece.

The invention provides a hologram laser comprising:

a hologram element mentioned above;

a light source for emitting light; and

a signal detection light-receiving element for receiving light returned from an information recording medium.

According to the invention, a hologram laser comprises a hologram element, a light source for emitting light, and a signal detection light-receiving element for receiving light returned from an information recording medium.

By achieving a reduction in areas of one bottom surface and another bottom surface of the hologram element, it is possible to reduce the area of bonding for mounting the hologram element in the hologram laser and thereby reduce the amount of a bonding material required to the mounting. This leads to cutting down on costs of the hologram laser.

The invention provides an optical pickup comprising:

a hologram laser for emitting light mentioned above; and

an optical component for directing light to an information recording medium.

According to the invention, a optical pickup comprises a hologram laser for emitting light and an optical component for directing light to an information recording medium.

By achieving a reduction in areas of one bottom surface and another bottom surface of the hologram element, it is possible to reduce the area of bonding for mounting the hologram element in the hologram laser and thereby reduce the amount of a bonding material required to the mounting. This leads to cutting down costs of the hologram laser, and thus to cutting down costs of the optical pickup which incorporates the hologram laser.

### BRIEF DESCRIPTION OF THE DRAWINGS

Other and further objects, features, and advantages of the invention will be more explicit from the following detailed description taken with reference to the drawings wherein:

FIG. 1A is a perspective view showing a hologram element 1 in accordance with a first embodiment of the invention;

FIG. 1B is a top view showing a hologram element in accordance with the first embodiment of the invention;

FIG. 1C is a schematic view showing a path through which light that passes through the hologram element of the first embodiment of the invention travels toward a signal detection light-receiving element;

FIG. 2A is a perspective view showing a hologram element in accordance with a second embodiment of the invention;

FIG. 2B is a top view showing a hologram element in accordance with the second embodiment of the invention;

FIG. 3A is a perspective view showing a hologram element in accordance with a third embodiment of the invention;

FIG. 3B is a top view showing a hologram element in accordance with the third embodiment of the invention;

FIG. 4A is a perspective view showing a hologram element in accordance with a fourth embodiment of the invention;

FIG. 4B is a top view showing a hologram element in accordance with the fourth embodiment of the invention;

FIG. 4C is a schematic view showing a path through which light that passes through the hologram element of the fourth embodiment of the invention travels toward a signal detection light-receiving element;

FIG. 5A is a perspective view showing a hologram element in accordance with a fifth embodiment of the invention;

FIG. 5B is a top view showing a hologram element in accordance with the fifth embodiment of the invention;

FIG. 6A is a perspective view showing a hologram element in accordance with a sixth embodiment of the invention;

FIG. 6B is a top view showing a hologram element in accordance with the sixth embodiment of the invention;

FIG. 7 is a top view showing a dicing configuration of a wafer that is adopted in a dicing operation to produce the hologram element in accordance with the first and fourth embodiments of the invention;

FIG. 8 is a top view showing a dicing configuration of the wafer that is adopted in a dicing operation to produce the hologram element in accordance with the second and fifth embodiments of the invention;

FIG. 9 is a top view showing a dicing configuration of the wafer that is adopted in a dicing operation to produce the hologram element in accordance with the third and sixth embodiments of the invention;

FIG. 10 is a flow chart for explaining a method to manufacture a hologram laser in which is mounted a hologram element in accordance with the invention;

FIGS. 11A through 11I are views for explaining the hologram laser manufacturing method;

FIG. 12 is a schematic view showing an optical pickup in which is mounted a hologram element in accordance with the invention;

FIG. 13A is a perspective view showing a hologram element of conventional design; and

FIG. 13B is a top view showing a hologram element of conventional design.

### DETAILED DESCRIPTION

Now referring to the drawings, preferred embodiments of the invention are described below.

First of all, a minimum necessary size required of a hologram element will be described. A minimum necessary area required of a hologram surface is determined based on the area of a hologram, the area of a region in which a grating surface is used by signal light coming from an optical disk, namely first-order diffraction light which arises as the result of diffraction of light entering from the hologram surface by the hologram, and the degree of an adhesive allowance necessary for fixing the hologram element to a separate optical component or the like, namely the area of contact with the separate optical component or the like.

Moreover, a minimum necessary area required of the grating surface is determined based on the area of a grating, the area of a region in which the grating surface is used by signal light coming from an optical disk, namely first-order diffraction light which arises as the result of diffraction of light entering from the hologram surface by the hologram, and the degree of an adhesive allowance necessary for fixing the hologram element to a separate optical component or the like, namely the area of contact with the separate optical component or the like.

The areas of the hologram and the grating must be secured to an extent that would completely cover a field of view provided by a collimator lens disposed in an optical pickup which employs the hologram element. The areas are determined with consideration given to all of the following factors: assembly tolerances for the device; variations in the field of view provided by the collimator lens resulting from a rocking motion of an objective lens which occurs at the time of performing a focusing servo to bring laser light into focus on a recording disk surface; and variations in the field of view provided by the collimator lens with respect to fluctuations in the wavelength of laser light resulting from temperature changes. Since these factors will be changed according to the optical design of the optical pickup in which is mounted the hologram element, for example, lens types and the length of an optical path, it follows that the necessary areas will be changed according to the individual optical design conditions correspondingly.

Just like the areas of the hologram and the grating, the area of the region in which the grating surface is used by diffraction light is determined, with consideration given to assembly tolerances for the device, variations in hologram diffraction angle resulting from wavelength fluctuations, and lens rocking motion-induced variations, in such a manner as to avoid that diffraction light passes through the grating. Moreover, there will be a change of an optical path for diffraction light depending on the relative arrangement of the hologram and a signal detection light-receiving element and the arrangement of a photo detector which is placed on the signal detection light-receiving element to receive diffraction light divided into two or three light beams by the hologram. With consideration given to the foregoing, in addition to the aforementioned variation factors, the necessary areas are determined properly.

According to a focusing servo technique called a knife edge method using a two-part or three-part split hologram, light which enters through the hologram surface basically illuminates a region lying in a line extending from, out of the hologram division line, the division line portion constituting the semicircular region. It is thus necessary to secure, in a direction in which the hologram division line extends, namely a direction in which the light entering from the hologram surface is diffracted, a region for allowing the passage of diffraction light through the grating surface.

The area of the adhesive allowance necessary for fixing the hologram element by an adhesive, namely the area of contact with a separate optical component or the like equates with the area of a region which makes no contribution to the attainment of an optical path. For example, the adhesive allowance is secured at the outer periphery of the hologram element in a width of 0.2 mm.

There is no particular limitation to the size and shape of the hologram element so long as the hologram surface and the grating surface thereof are each given the minimum necessary area described thus far. However, in view of a dicing operation, if the hologram element is designed to have a too complex shape, the dicing operation will be difficult or impossible. It is thus desirable that the shape be such that a wafer can be shaped to be in the form of chips by cutting using as few the number of dicing lines as possible and also there is no needless region in the wafer to be discarded.

The thickness of the hologram element, namely the distance between the hologram surface and the grating surface is under restrictions in several ways with regard to the optical path of diffraction light. Firstly, in terms of the necessity to avoid the passage of diffraction light through the grating, the smaller is the thickness of the hologram element, the larger diffraction angle has to be obtained. An increase in diffraction angle cannot be achieved without making the rectangular conformation of the hologram pattern finer than ever; that is, making the peak-to-valley pitch thereof finer than ever. This entails manufacturing limitations. Furthermore, in regard to the area of the grating surface portion occupied by diffraction light, the smaller is the thickness of the hologram element, the larger is the occupied area. This makes down-sizing of the hologram element difficult.

By way of contrast, in the case of increasing the thickness of the hologram element, a wafer substrate for use will be more costly apiece, which results in rising costs. Furthermore, the increase of the thickness gives rise to cost-related problems such as excessive wearing out of the dicing edge, and also a problem of an undesirable increase in the size of the device main body. In order to strike a proper balance, the thickness of the hologram element is set at 2 mm.

Holograms are classified into a two-part split hologram and a three-part split hologram. The choice of which hologram to use is determined by a signal processing method selected from the one adaptable to CD and the one adaptable to DVD that differ from each other. In the case of DVD, one of the semicircular hologram portions of a hologram, which is not used in a focusing servo, is further divided into two parts whereby to split light entering from the hologram surface. The above-described theory about the minimum necessary size required of the hologram element holds true for either of the two-part split hologram and the three-part split hologram.

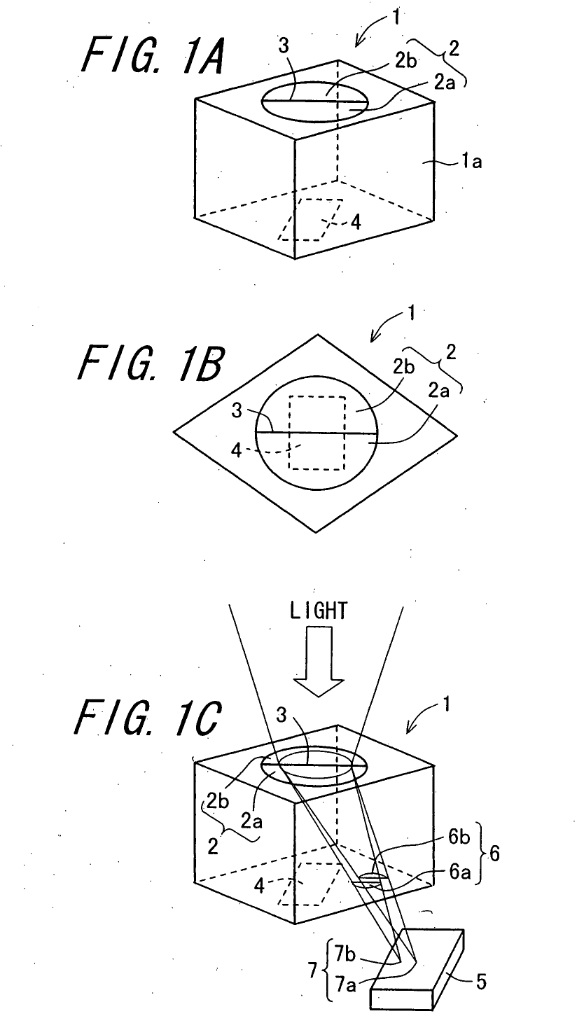

FIG. 1A is a perspective view showing a hologram element 1 in accordance with a first embodiment of the invention, and FIG. 1B is a top view showing a hologram element 1 in accordance with the first embodiment of the invention. The hologram element 1 is composed of a hologram element body 1a shaped as a right prism which has two bottom surfaces, and its bottom surfaces have a shape of a rhombus. A circular hologram 2 is disposed on a hologram surface which is one of the bottom surfaces. The hologram 2 is divided into two semicircular regions 2a and 2b by a division line 3. The regions 2a and 2b have different grating periods. Moreover, a grating 4 is disposed on a grating surface, which is another of the bottom surfaces, opposite the hologram surface. On the hologram surface, a first diagonal line is longer than a second diagonal line. The center of the hologram 2 is located at a point of intersection of the first diagonal line and the second diagonal line, and the division line 3 lies in the first diagonal line.

FIG. 1C is a schematic view showing a path through which light that passes through the hologram element 1 of the first embodiment of the invention travels toward a signal detection light-receiving element. The light entering from the hologram surface is diffracted to be first-order diffraction light. The first-order diffraction light is directed to the signal detection light-receiving element 5. A diffraction light beam passing through the region 2a and a diffraction light beam passing through the region 2b, now diffracted by the respective gratings having different periods, pass through grating surface passage regions 6a and 6b, respectively, and are then condensed on spots 7a and 7b, respectively, on the signal detection light-receiving element 5.

The light which enters through the hologram surface illuminates a plane which is perpendicular to the hologram surface and includes the division line 3, as the spots 7a and 7b. In order to secure the grating surface passage regions 6a and 6b on the grating surface, in a direction in which the light entering from the hologram surface is diffracted, the hologram element is so configured that its hologram surface and grating surface have the shape of a rhombus, and the division line 3 lies in the first diagonal line which is a longer one of the diagonal lines of the rhombus. This makes it possible to secure a sufficient length in a direction in which the division line 3 of the hologram surface extends while reducing the areas of the hologram surface and the grating surface. By reducing the areas of the hologram surface and the grating surface, it is possible to reduce the substantial cubic volume of the hologram element and thereby achieve miniaturization without impairing the optical capability required of the hologram element. In regard to the embodiments described hereinbelow, even if the hologram surface and the grating surface are each formed in the shape of an isosceles triangle or a regular triangle, substantially the same effects can be attained.

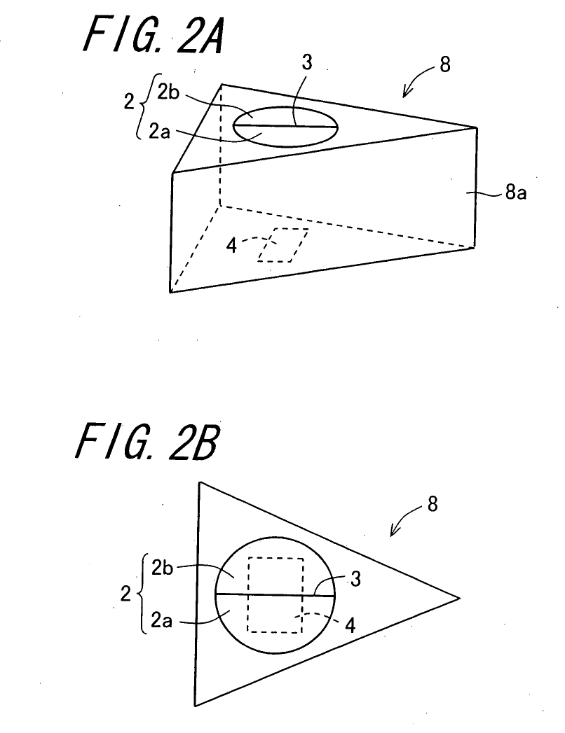

FIG. 2A is a perspective view showing a hologram element 8 in accordance with a second embodiment of the invention, and FIG. 2B is a top view showing a hologram element 8 in accordance with the second embodiment of the invention. The hologram element 8 is composed of a hologram element body 8a shaped as a right prism which has two bottom surfaces, and its bottom surfaces have a shape of an isosceles triangle. A circular hologram 2 is disposed on a hologram surface which is one of the bottom surfaces. The hologram 2 is divided into two semicircular regions 2a and 2b by a division line 3. The regions 2a and 2b have different grating periods. Moreover, a grating 4 is disposed on a grating surface, which is another of the bottom surfaces, opposite the hologram surface. The division line lies in a bisector of the vertex angle of the isosceles triangle.

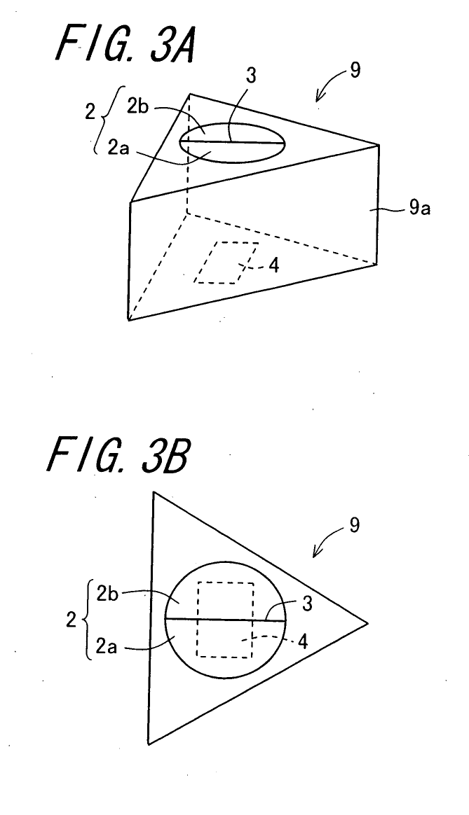

FIG. 3A is a perspective view showing a hologram element 9 in accordance with a third embodiment of the invention, and FIG. 3B is a top view showing a hologram element 9 in accordance with the third embodiment of the invention. The hologram element 9 is composed of a hologram element 9a shaped as a right prism which has two bottom surfaces, and its bottom surfaces have a shape of a regular triangle. A circular hologram 2 is disposed on a hologram surface which is one of the bottom surfaces. The hologram 2 is divided into two semicircular regions 2a and 2b by a division line 3. The regions 2a and 2b have different grating periods. Moreover, a grating 4 is disposed on a grating surface, which is another of the bottom surfaces, opposite the hologram surface. The division line 3 lies in a bisector of any of the angles of the regular triangle.

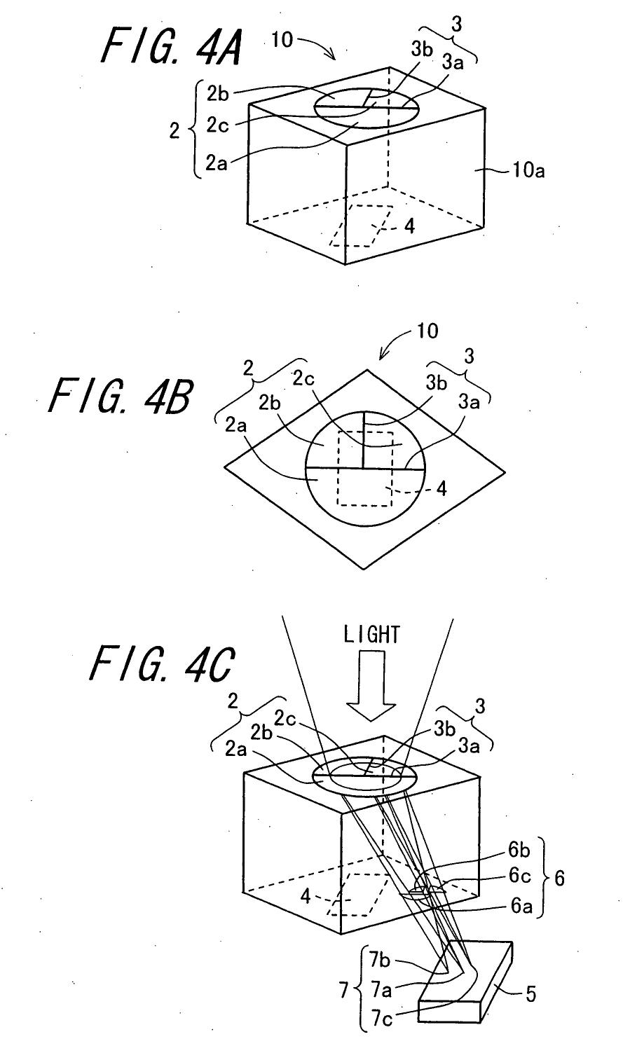

FIG. 4A is a perspective view showing a hologram element 10 in accordance with a fourth embodiment of the invention, and FIG. 4B is a top view showing a hologram element 10 in accordance with the fourth embodiment of the invention. The hologram element 10 is composed of a hologram element body 10a shaped as a right prism which has two bottom surfaces, and its bottom surfaces have a shape of a rhombus. A circular hologram 2 is disposed on a hologram surface which is one of the bottom surfaces. The hologram 2 is divided by a division line 3a into two semicircular regions, one of which is a region 2a, and the other is further divided into two regions 2b and 2c by a division line 3b. In this way, the hologram 2 is divided into three regions 2a through 2c having different grating periods. Moreover, a grating 4 is disposed on a grating surface, which is another of the bottom surfaces, opposite the hologram surface. On the hologram surface, a first diagonal line is longer than a second diagonal line. The center of the hologram 2 is located at a point of intersection of the first diagonal line and the second diagonal line, and the division line 3a lies in the first diagonal line.

FIG. 4C is a schematic view showing a path through which light that passes through the hologram element 10 of the fourth embodiment of the invention travels toward a signal detection light-receiving element. The light entering from the hologram surface is diffracted to be first-order diffraction light. The first-order diffraction light is directed to the signal detection light-receiving element 5. A diffraction light beam passing through the region 2a, a diffraction light beam passing through the region 2b, and a diffraction light beam passing through the region 2c, now diffracted by the respective gratings having different periods, pass through grating surface passage regions 6a through 6c, respectively, and are then condensed on spots 7a through 7c, respectively, on the signal detection light-receiving element 5.

The light which enters through the hologram surface illuminates a plane which is perpendicular to the bottom surfaces and includes the division line 3a, as the spots 7a through 7c. It is thus necessary to secure, in a direction in which, the light entering from the hologram surface is diffracted, the grating surface passage regions 6a through 6c on the grating surface. Accordingly, the hologram element is so configured that the hologram surface and grating surface have the shape of a rhombus, and the division line 3a lies in the first diagonal line which is a longer one of the diagonal lines of the rhombus. This makes it possible to secure a sufficient length in a direction in which the division line 3a of the hologram surface extends while reducing the areas of the hologram surface and the grating surface. By reducing the areas of the hologram surface and the grating surface, it is possible to reduce the substantial cubic volume of the hologram element and thereby achieve miniaturization without impairing the optical capability required of the hologram element. In regard to the embodiments described hereinbelow, even if the hologram surface and the grating surface are each formed in the shape of an isosceles triangle or a regular triangle, substantially the same effects can be attained.

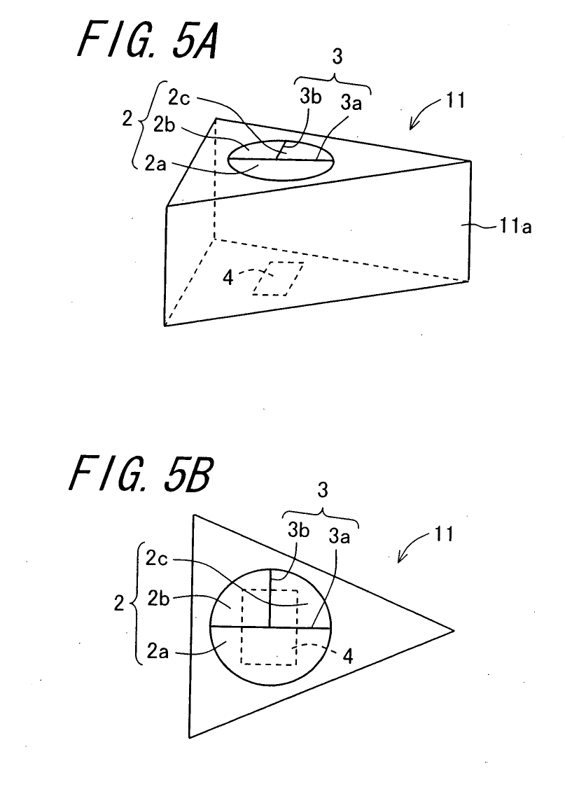

FIG. 5A is a perspective view showing a hologram element 11 in accordance with a fifth embodiment of the invention, and FIG. 5B is a top view showing a hologram element 11 in accordance with the fifth embodiment of the invention. The hologram element 11 is composed of a hologram element body 11a shaped as a right prism which has two bottom surfaces, and its bottom surfaces have a shape of an isosceles triangle. A circular hologram 2 is disposed on a hologram surface which is one of the bottom surfaces. The hologram 2 is divided by a division line 3a into two semicircular regions, one of which is a region 2a, and the other is further divided into two regions 2b and 2c by a division line 3b. In this way, the hologram 2 is divided into three regions 2a through 2c having different grating periods. Moreover, a grating 4 is disposed on a grating surface, which is another of the bottom surfaces, opposite the hologram surface. The division line 3a lies in a bisector of the vertex angle of the isosceles triangle.

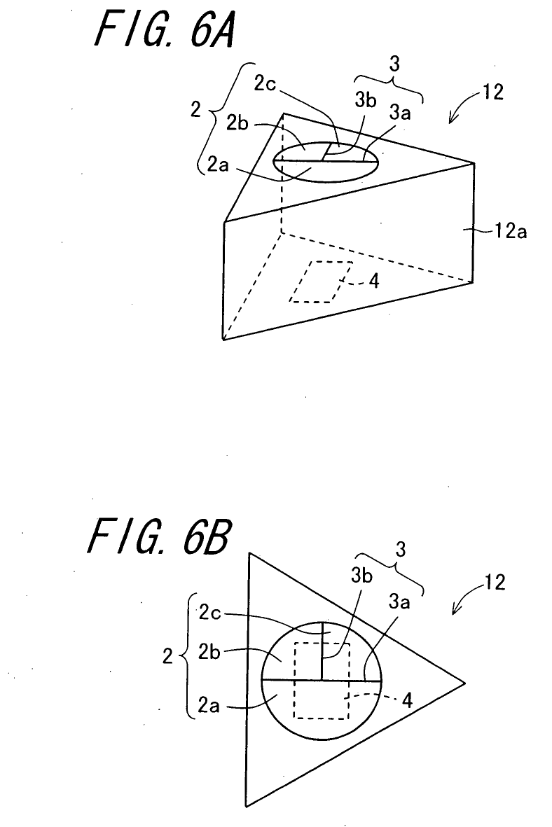

FIG. 6A is a perspective view showing a hologram element 12 in accordance with a sixth embodiment of the invention, and FIG. 6B is a top view showing a hologram element 12 in accordance with the sixth embodiment of the invention. The hologram element 12 is composed of a hologram element body 12a shaped as a right prism which has two bottom surfaces, and its bottom surfaces have a shape of a regular triangle. A circular hologram 2 is disposed on a hologram surface which is one of the bottom surfaces. The hologram 2 is divided by a division line 3a into two semicircular regions, one of which is a region 2a, and the other is further divided into two regions 2b and 2c by a division line 3b. In this way, the hologram 2 is divided into three regions 2a through 2c having different grating periods. Moreover, a grating 4 is disposed on a grating surface, which is another of the bottom surfaces, opposite the hologram surface. The division line 3a lies in a bisector of any of the angles of the regular triangle.

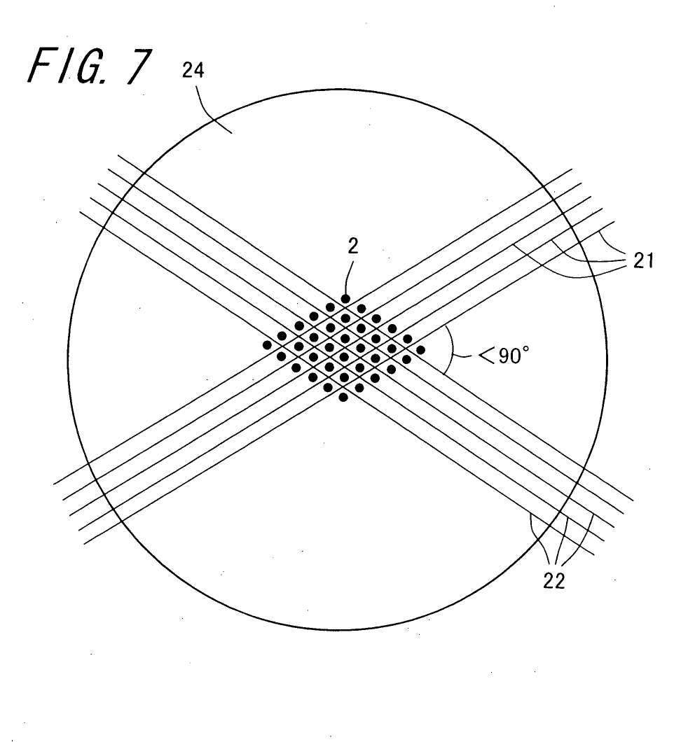

FIG. 7 is a top view showing a dicing configuration of a wafer 24 that is adopted in a dicing operation to produce the hologram elements 1 and 10, which have rhombus-shaped bottom surfaces, in accordance with the first and fourth embodiments of the invention. In the dicing operation, the wafer 24 having a plurality of holograms 2 and a plurality of gratings 4 formed on its upper surface and non-illustrated lower surface, respectively, is cut into chips. At this time, the wafer 24 is subjected to cutting in accordance with equi-spaced first cutting lines 21 and equi-spaced second cutting lines 22. The first cutting line 21 and the second cutting line 22 make an acute angle with each other. A point of intersection of the first cutting line 21 and the second cutting line 22 lies in a line extending from the division line 3 of the hologram 2, as well as in a line extending from the perpendicular bisector of the division line 3. Moreover, the division line 3 lies in the bisector of the acute angle which the first cutting line 21 forms with the second cutting line 22.

The number of hologram elements to be obtained per wafer is inversely proportional to the size of a chip. Accordingly, when calculated on the basis of the area ratio of the hologram's bottom surface, it has been found that the hologram element having rhombus-shaped bottom surfaces is 1.52 times as large as the conventional one having rectangular-shaped bottom surfaces in number of production per wafer. Note that the number of hologram elements having rectangular-shaped bottom surfaces to be obtained per wafer is 970 (970 chips). Shown in FIG. 7 is merely part of the holograms 2 formed on the wafer 24, and in reality, the holograms 2 are formed over the entire surface of the wafer 24. Also in regard to the dicing operation, the entire surface of the wafer 24 is subjected to cutting in accordance with the first cutting lines 21 and the second cutting lines 22.

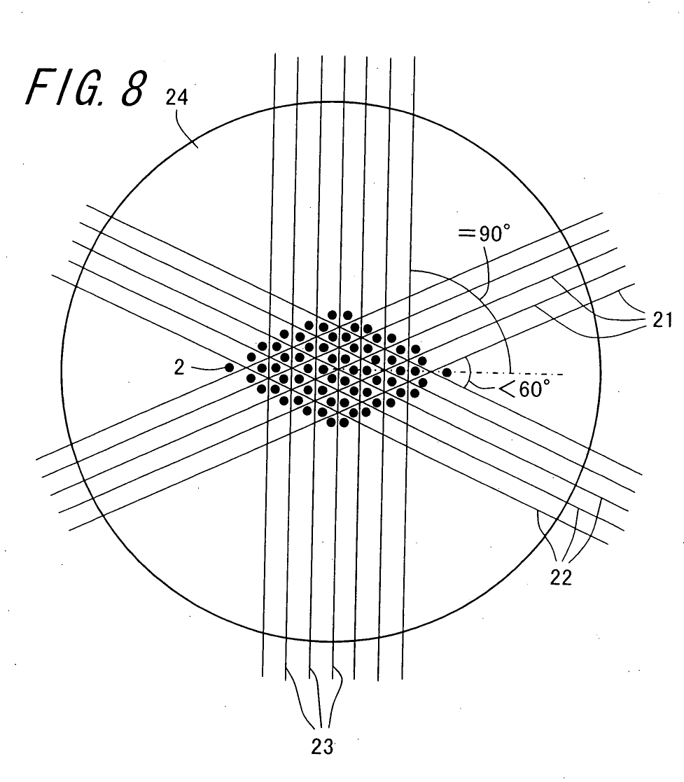

FIG. 8 is a top view showing a dicing configuration of the wafer 24 that is adopted in a dicing operation to produce the hologram elements 8 and 11, which have isosceles triangle-shaped bottom surfaces, in accordance with the second and fifth embodiments of the invention.

Prior to the dicing operation, there is carried out a formation step of forming holograms and gratings on the wafer. In this formation step, the holograms and the gratings are formed so as to be each 180° rotationally symmetrical with a hologram or grating adjacent thereto, about centers of the holograms and the gratings each regarded as a center of rotation.

In the dicing operation, the wafer 24 having a plurality of holograms 2 and a plurality of gratings 4 formed on its upper surface and non-illustrated lower surface, respectively, is cut into chips. At this time, the wafer 24 is subjected to cutting in accordance with equi-spaced first cutting lines 21, equi-spaced second cutting lines 22, and equi-spaced third cutting lines 23. The first cutting line 21 and the second cutting line 22 make an acute angle with each other. The third cutting line 23 lies in the perpendicular bisector of an obtuse angle which the first cutting line 21 forms with the second cutting line 22. Moreover, the division line 3 lies in the bisector of the obtuse angle which the first cutting line 21 forms with the second cutting line 22.

The number of hologram elements to be obtained per wafer is inversely proportional to the size of a chip. Accordingly, when calculated on the basis of the area ratio of the hologram's bottom surface, it has been found that the hologram element having isosceles triangle-shaped bottom surfaces is 1.47 times as large as the conventional one having rectangular-shaped bottom surfaces in number of production per wafer. Note that the number of hologram elements having rectangular-shaped bottom surfaces to be obtained per wafer is 970 (970 chips). Shown in FIG. 8 is merely part of the holograms 2 formed on the wafer 24, and in reality, the holograms 2 are formed over the entire surface of the wafer 24. Also in regard to the dicing operation, the entire surface of the wafer 24 is subjected to cutting in accordance with the first cutting lines 21, the second cutting lines 22, and the third cutting lines 23.

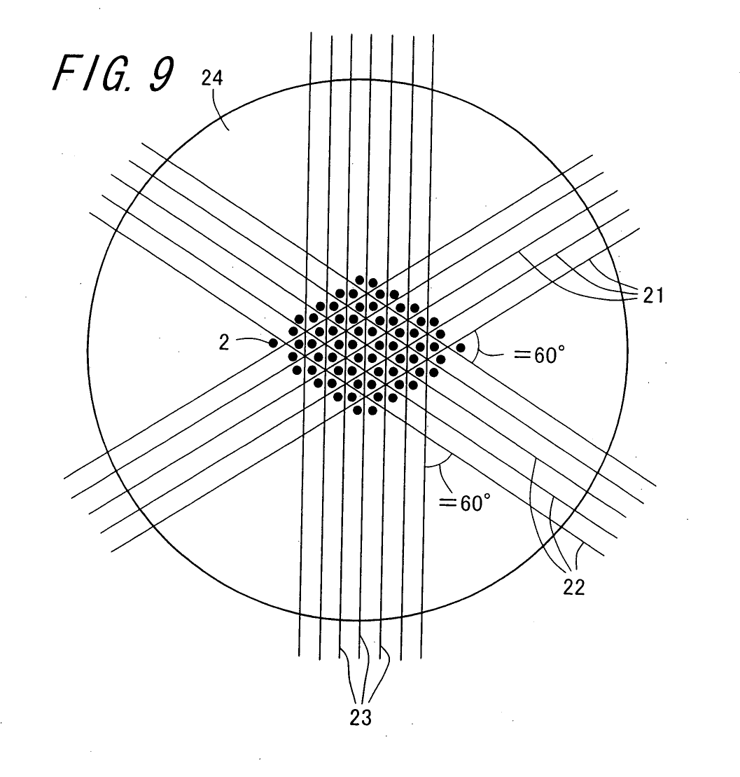

FIG. 9 is a top view showing a dicing configuration of the wafer 24 that is adopted in a dicing operation to produce the hologram elements 9 and 12, which have regular triangle-shaped bottom surfaces, in accordance with the third and sixth embodiments of the invention.

Prior to the dicing operation, there is carried out a formation step of forming holograms and gratings on the wafer. In this formation step, the holograms and the gratings are formed so as to be each 180° rotationally symmetrical with a hologram or grating adjacent thereto, about centers of the holograms and the gratings each regarded as a center of rotation.

In the dicing operation, the wafer 24 having a plurality of holograms 2 and a plurality of gratings 4 formed on its upper surface and non-illustrated lower surface, respectively, is cut into chips. At this time, the wafer 24 is subjected to cutting in accordance with equi-spaced first cutting lines 21, equi-spaced second cutting lines 22, and equi-spaced third cutting lines 23. The first cutting line 21, the second cutting line 22, and the third cutting line 23 make an angle of 60° with one another. Moreover, the division line 3 lies in the bisector of the acute angle which the first cutting line 21 forms with the second cutting line 22.

The number of hologram elements to be obtained per wafer is inversely proportional to the size of a chip. Accordingly, when calculated on the basis of the area ratio of the hologram's bottom surface, it has been found that the hologram element having regular triangle-shaped bottom surfaces is 1.58 times as large as the conventional one having rectangular-shaped bottom surfaces in number of production per wafer. Note that the number of hologram elements having rectangular-shaped bottom surfaces to be obtained per wafer is 970 (970 chips). Shown in FIG. 9 is merely part of the holograms 2 formed on the wafer 24, and in reality, the holograms 2 are formed over the entire surface of the wafer 24. Also in regard to the dicing operation, the entire surface of the wafer 24 is subjected to cutting in accordance with the first cutting lines 21, the second cutting lines 22, and the third cutting lines 23.

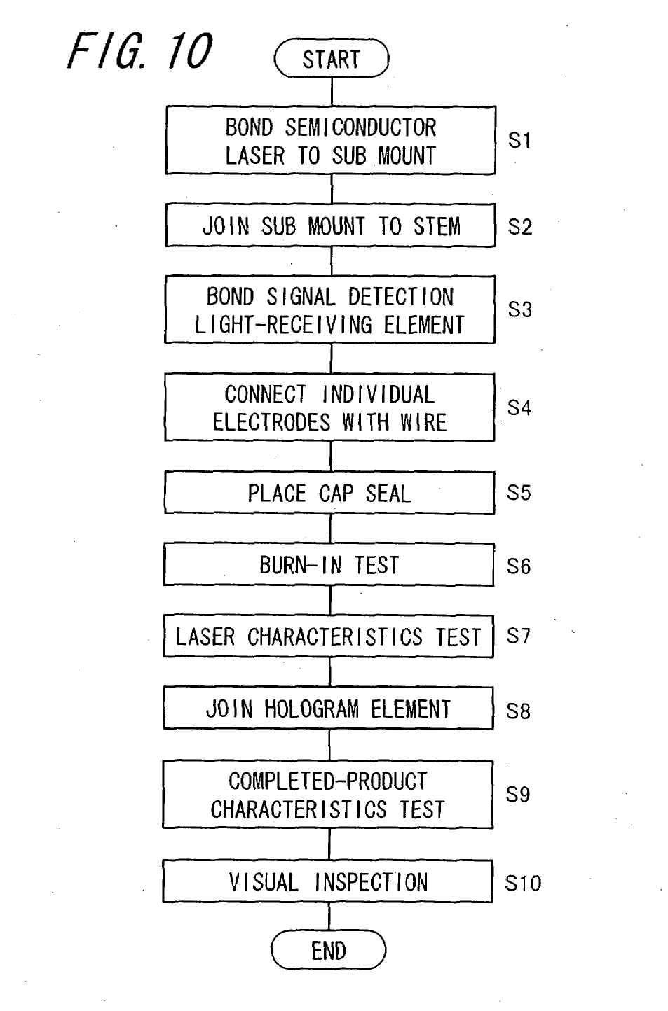

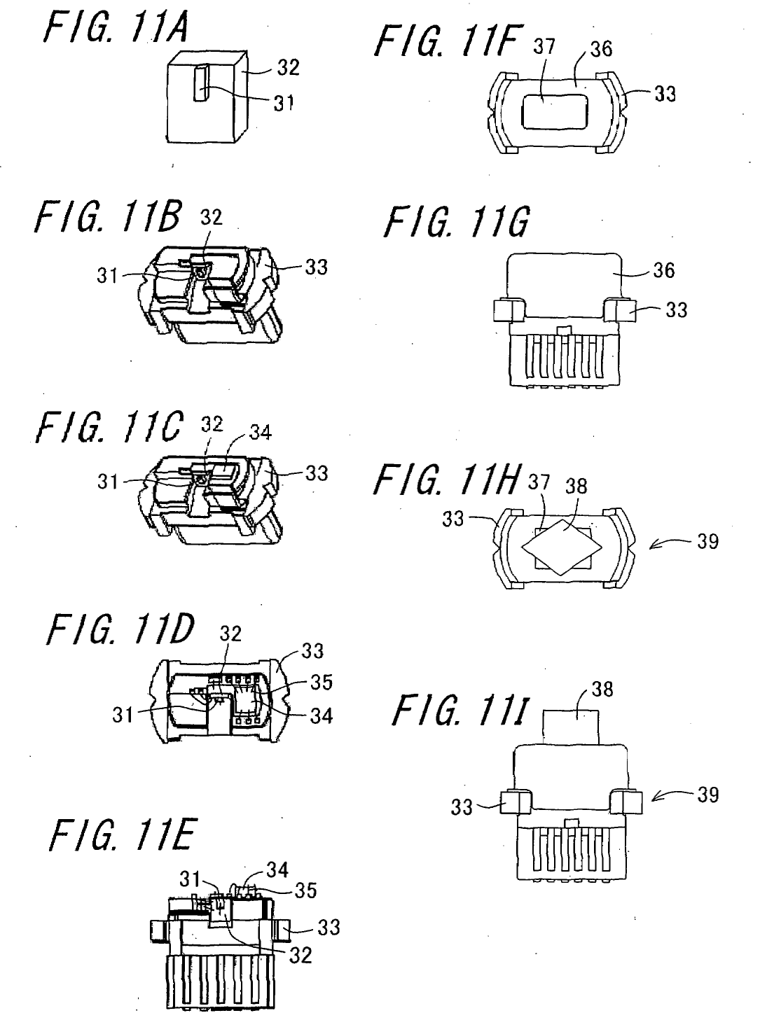

FIG. 10 is a flow chart for explaining a method to manufacture a hologram laser 39 in which is mounted a hologram element 38 according to the invention. FIGS. 11A through 11I are views for explaining the hologram laser manufacturing method.

At the outset, a semiconductor laser element 31 acting as a light source is bonded to a sub mount 32 (Step S1). Then, the sub mount 32 having bonded thereto the semiconductor laser element 31 is joined to a predetermined position of a stem 33 (Step S2). Further, a signal detection light-receiving element 34 is mounted on the stem 33 (Step S3). FIGS. 11A through 11C are perspective views showing the steps that correspond to Steps S1 through S3, respectively.

Next, the connections of individual electrodes are established by means of wire 35 (Step S4), and a cap 36 is placed to cover that side of the stem 33 on which are mounted the optical components (Step S5). FIGS. 11D and 11E are a top view and a side view, respectively, showing the step corresponding to Step S4. FIGS. 11F and 11G are a top view and a side view, respectively, showing the step corresponding to Step S5. On the upper part of the cap 36 is formed a window 37. The window 37 can be designed in any given shape so long as it does not interfere with the hologram element bonding strength and the optical path.

Following the completion of a burn-in test to accelerate quality degradation of a test specimen through application of heat at certain temperature and voltage, which is performed to get rid of infant mortality failures in advance so that time reduction can be achieved (Step S6), and a laser characteristics test (Step S7), the rhombus-shaped hologram element 38 is joined to the upper part of the window 37 of the cap 36 (Step S8). FIGS. 11H and 11I are a top view and a side view, respectively, showing the step corresponding to Step S8. In the case of handling the hologram element 38 having a rhombus shape, the diagonally angular portions thereof are held sideways by an L-shaped chucking pawl. In this state, the hologram element 38 is subjected to position adjustment and bonding with use of a bonding apparatus. Even if the hologram element 38 has a triangle shape, by making a change to the shape of the chucking pawl suitably, the hologram element 38 can be held thereby in a similar manner, whereby making it possible to allow easy position adjustment and bonding with use of a bonding apparatus.

The window 37 can be designed in any given shape so long as it does not interfere with the hologram element 38 bonding strength and the optical path. For example, the rhombus-shaped hologram element 38 can be fixed to the rectangular-shaped window 37 only at its rhombus vertices by means of an adhesive or otherwise. This is true for the case where the hologram element 38 has a triangle shape. The window 37 does not necessarily have to be covered by the hologram element 38, and thus the construction can be designed as an open-type device. However, if there is a usage condition for the device such as that it is used in adverse environments where wide temperature variations which could lead to occurrence of condensation are encountered, the device needs to be designed as a hermetic-type device. It is thus necessary to make a change to the shape of the window 37 in conformity with the shape of the hologram element 38. That is, in this case, there is a need for a hermetic-type device in which the to-be-bonded portion of the hologram element 38 is adhesively sealed throughout its periphery. The shape of the window 37 can be changed with ease by making a change to the configuration of a die for use.

The hologram laser 39 in finished form is subjected to completed-product characteristics test (Step S9) and a visual inspection (Step S10) to be ready for shipment.

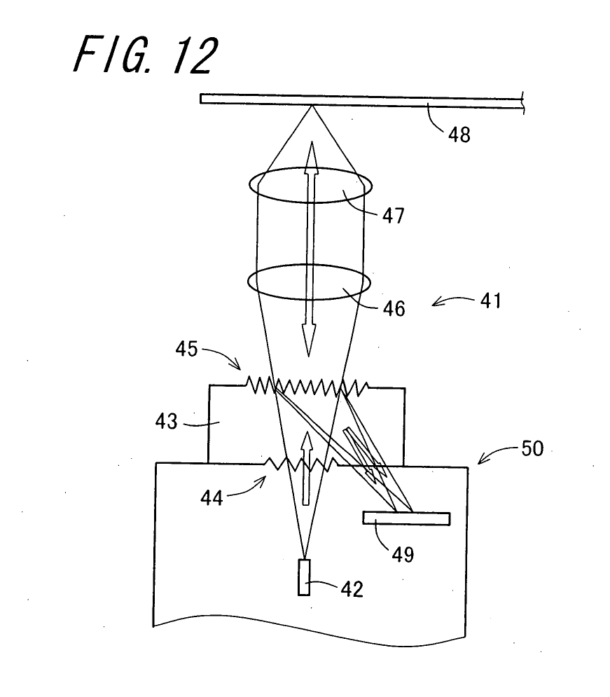

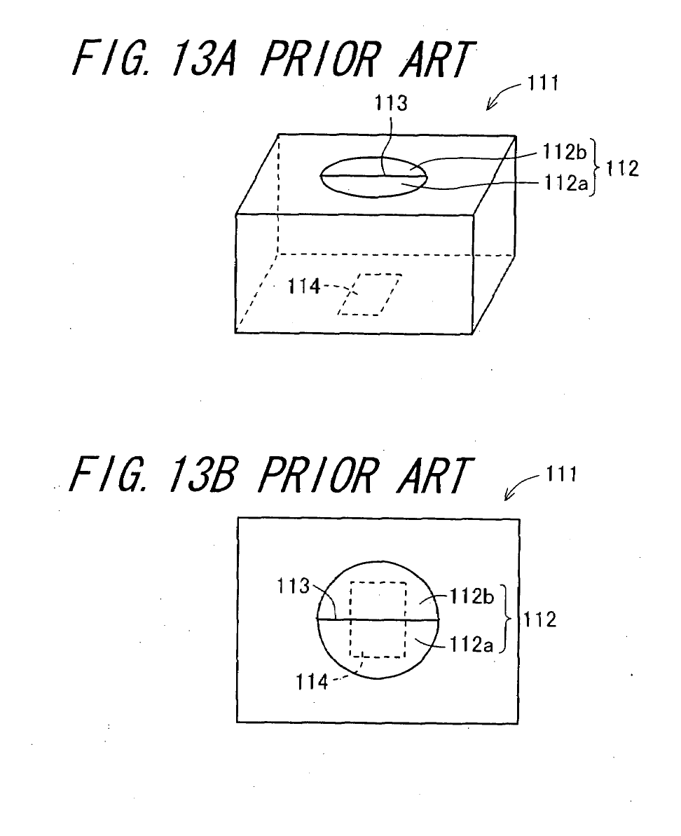

FIG. 12 is a schematic view showing an optical pickup 41 in which is mounted a hologram element 43 embodying the invention. With use of the optical pickup 41, reproduction, recording, or erasing of information borne on an optical disk 48 can be carried out. The optical pickup 41 is composed of a hologram laser 50, a collimator lens 46, and an objective lens 47. The hologram laser 50 is composed of a combination of a semiconductor laser element 42, the hologram element 43, and a signal detection light-receiving element 49 in a single-piece construction. Moreover, the arrow in the figure indicates an optical path.

Light emitted from the semiconductor laser element 42 acting as a light source passes through a grating 44 and a hologram 45 of the hologram element 43, and is then turned into collimated light by the collimator lens 46. The collimated light enters the objective lens 47 so as to converge on the optical disk 48, and is eventually focused to a minute spot. The light reflected from the optical disk 48 returns to the objective lens 47 as signal light. The signal light passes through the collimator lens 46, and is then diffracted by the hologram 45 of the hologram element 43. The diffraction light illuminates the signal detection light-receiving element 49. Whereupon, the signal detection light-receiving element 49 detects signal information and servo signals provided from the optical disk 48 so as to achieve recoding or reproduction of the information.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A hologram element comprising:
a hologram element body shaped as a right prism having rhombus-shaped bottom surfaces;
a hologram disposed on one of the bottom surfaces of the hologram element body, the hologram being divided by a division line into a plurality of regions having different grating periods; and
a grating disposed on another of the bottom surfaces of the hologram element body,
on the rhombus-shaped bottom surface, a first diagonal line of the respective rhombus-shaped bottom surfaces being longer than a second diagonal line thereof,
a center of the hologram being located at a point of intersection of the first diagonal line and the second diagonal line,
the division line lying in the first diagonal line, and
light which enters through the one bottom surface having the hologram illuminating a plane which is perpendicular to the one bottom surface and includes the division line.

2. A hologram element comprising:
a hologram element body shaped as a right prism having isosceles triangle-shaped bottom surfaces;
a hologram disposed on one of the bottom surfaces of the hologram element body, the hologram being divided by a division line into a plurality of regions having different grating periods; and
a grating disposed on another of the bottom surfaces of the hologram element body,
the division line lying in a bisector of a vertex angle of the isosceles triangle-shaped bottom surface, and
light which enters through the one bottom surface having the hologram illuminating, out of a plane which is perpendicular to the one bottom surface and includes the division line, a region located closer to the vertex angle of the isosceles triangle-shaped bottom surface relative to a center of the hologram.

3. A hologram element comprising:
a hologram element body shaped as a right prism having regular triangle-shaped bottom surfaces;
a hologram disposed on one of the bottom surfaces of the hologram element body, the hologram being divided by a division line into a plurality of regions having different grating periods; and
a grating disposed on another of the bottom surfaces of the hologram element body,
the division line lying in a bisector of any of the angles of the regular triangle-shaped bottom surface,
light which enters through the one bottom-surface having the hologram illuminating, out of a plane which is perpendicular to the one bottom surface and includes the division line, a region located closer to the angle of the regular triangle-shaped bottom surface relative to a center of the hologram.

4. A method for manufacturing a hologram element of claim 1, comprising:
a dicing step of cutting a wafer having a plurality of the holograms and the gratings into chips,
in the dicing step, the wafer being subjected to cutting in accordance with equi-spaced first cutting lines and equi-spaced second cutting lines,
the first cutting line and the second cutting line making an acute angle with each other,
a point of intersection of the first cutting line and the second cutting line lying in a line extending from the division line, as well as in a line extending from a perpendicular bisector of the division line, and
the division line lying in a bisector of the acute angle.

5. A method for manufacturing a hologram element of claim 2, comprising:
a formation step of forming holograms and gratings on a wafer; and
a dicing step of cutting the wafer having a plurality of the holograms and the gratings into chips,
in the formation step, the holograms and the gratings being formed so as to be each 180° rotationally symmetrical with a hologram or grating adjacent thereto, about centers of the holograms and the gratings each regarded as a center of rotation,
and in the dicing step, the wafer being subjected to cutting in accordance with equi-spaced first cutting lines, equi-spaced second cutting lines, and equi-spaced third cutting lines; the first cutting line and the second cutting line making an acute angle of smaller than 60° with each other; the third cutting line lying in a perpendicular bisector of an obtuse angle which the first cutting line forms with the second cutting line; and the division line lying in a bisector of the acute angle.

6. A method for manufacturing a hologram element of claim 3, comprising:
a formation step of forming holograms and gratings on a wafer; and
a dicing step of cutting the wafer having a plurality of the holograms and the gratings into chips,
in the formation step, the holograms and the gratings being formed so as to be each 180° rotationally symmetrical with a hologram or grating adjacent thereto, about centers of the holograms and the gratings each regarded as a center of rotation,
and in the dicing step, the wafer being subjected to cutting in accordance with equi-spaced first cutting lines, equi-spaced second cutting lines, and equi-spaced third cutting lines; the first cutting line, the second cutting line, and the third cutting line make an angle of 60° with one another; and the division line lies in a bisector of the angle which the first cutting line forms with the second cutting line.

7. A hologram laser comprising:
a hologram element of claim 1;
a light source for emitting light; and
a signal detection light-receiving element for receiving light returned from an information recording medium.

8. A hologram laser comprising:
a hologram element of claim 2;
a light source for emitting light; and
a signal detection light-receiving element for receiving light returned from an information recording medium.

9. A hologram laser comprising:
a hologram element of claim 3;
a light source for emitting light; and
a signal detection light-receiving element for receiving light returned from an information recording medium.

10. An optical pickup comprising:
a hologram laser for emitting light of claim 7; and
an optical component for directing light to an information recording medium.

11. An optical pickup comprising:
a hologram laser for emitting light of claim 8; and
an optical component for directing light to an information recording medium.

12. An optical pickup comprising:
a hologram laser for emitting light of claim 9; and
an optical component for directing light to an information recording medium.
